(19) United States
(12) Patent Application Publication
(10) Pub. No.: US 2026/0036652 A1
(43) Pub. Date: Feb. 5, 2026

(54) PROCESSING SYSTEM, PROCESSING METHOD, AND RECORDING MEDIUM

(71) Applicant: NEC Corporation, Tokyo (JP)

(72) Inventors: Aiko YAMAGUCHI, Tokyo (JP); Yohei KAWAKAMI, Tokyo (JP)

(73) Assignee: NEC Corporation, Tokyo (JP)

(21) Appl. No.: 19/269,532

(22) Filed: Jul. 15, 2025

(30) Foreign Application Priority Data
Jul. 31, 2024 (JP) 2024-125026

(51) Int. Cl. G01R 33/035; G06N 10/40

(52) U.S. Cl. CPC G01R 33/0356; G06N 10/40

(57) ABSTRACT

A processing system includes: at least one memory storing instructions; and at least one processor configured to execute the instructions to: calculate a first current value based on a value of a residual magnetic flux in a resonator circuit included in a quantum bit device, the first current value being a current value of a current flowing through the resonator circuit.

This application is based upon and claims the benefit of priority from Japanese patent application No. 2024-125026, filed on Jul. 31, 2024, the disclosure of which is incorporated herein in its entirety by reference.

### TECHNICAL FIELD

The present disclosure relates to a processing system, a processing method, and a recording medium.

### BACKGROUND ART

A quantum computer has been developed as one of increasing speed of a computer calculation processing. JP 2023-554256 A discloses a technique related to a quantum computing device as a related technique.

### SUMMARY

In a technical field related to a quantum computer such as JP 2023-554256 A, a technology capable of accurately adjusting a resonance frequency in a quantum bit device is required.

An object of each aspect of the present disclosure is to provide a processing system, a processing method, and a program that can solve the above problems.

According to one aspect of the present disclosure, a processing system includes a calculation means for calculating a first current value based on a value of a residual magnetic flux in a resonator circuit included in a quantum bit device, the first current value being a current value of a current flowing through the resonator circuit.

According to another aspect of the present disclosure, a processing method includes calculating a first current value based on a value of a residual magnetic flux in a resonator circuit included in a quantum bit device, the first current value being a current value of a current flowing through the resonator circuit.

According to another further aspect of the present disclosure, a non-transitory computer-readable recording medium having recorded therein a program causes a computer to execute calculating a first current value based on a value of a residual magnetic flux in a resonator circuit included in a quantum bit device, the first current value being a current value of a current flowing through the resonator circuit.

According to each aspect of the present disclosure, the resonance frequency can be accurately adjusted.

### BRIEF DESCRIPTION OF THE DRAWINGS

Exemplary features and advantages of the present disclosure will become apparent from the following detailed description when taken with the accompanying drawings in which:

FIG. 1 is a diagram illustrating an example of a circuit according to some example embodiments of the present disclosure;

FIG. 2 is a diagram illustrating an example of a circuit according to some example embodiments of the present disclosure;

FIG. 3 is a diagram showing an example of magnetic field dependency of a resonance frequency of a quantum bit device in some example embodiments of the present disclosure;

FIG. 4 is a diagram illustrating an example of a configuration of a processing system according to some example embodiments of the present disclosure;

FIG. 5 is a diagram illustrating an example of a processing flow of a processing system according to some example embodiments of the present disclosure;

FIG. 6 is a diagram illustrating an example of a measurement result by a frequency measuring device according to some example embodiments of the present disclosure;

FIG. 7 is a diagram illustrating an example of a processing flow of a processing system according to some example embodiments of the present disclosure;

FIG. 8 is a diagram illustrating an example of a circuit according to some example embodiments of the present disclosure;

FIG. 9 is a diagram illustrating an example of a configuration of a processing system according to some example embodiments of the present disclosure;

FIG. 10 is a diagram illustrating an example of a processing flow of a processing system according to some example embodiments of the present disclosure; and

FIG. 11 is a schematic block diagram illustrating a configuration of a computer according to at least one example embodiment.

### EXAMPLE EMBODIMENT

Hereinafter, example embodiments will be described in detail with reference to the drawings.

### Example Embodiment

A processing system 1 according to one example embodiment of the present disclosure will be described with reference to the drawings. The processing system 1 is a system that configures a superconducting quantum bit device by using a superconducting quantum interference device (Superconducting Quantum Interference Device, hereinafter described as “SQUID”). As described later, the processing system 1 calculates a current value flowing through a bias line inductively coupled to the SQUID loop to be set in consideration of a residual magnetic flux inside the SQUID loop, and sets the current value. Thereafter, the processing system 1 again takes in the error between the resonance frequency to set and the resonance frequency observed by measurement as the residual magnetic flux, calculates the current value again, sets the current value, and confirms the resonance frequency by measurement. The processing system 1 adjusts the resonance frequency by repeating this operation.

### (Method of Adjusting Resonance Frequency)

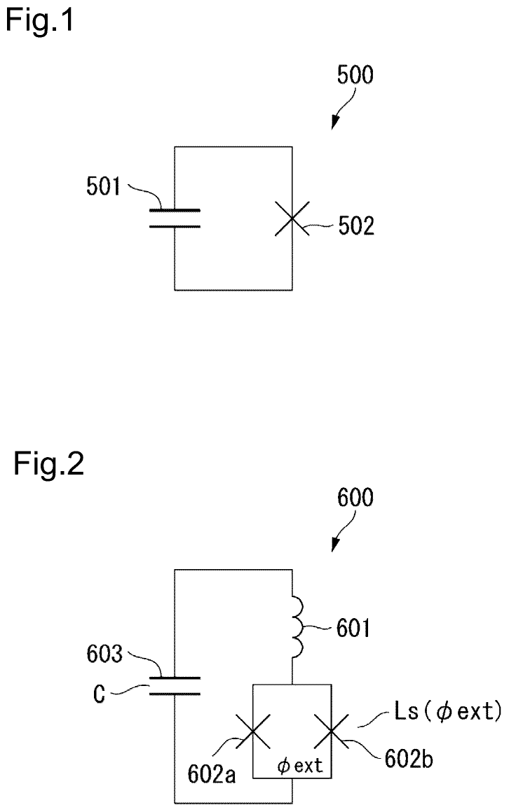

A method of adjusting a resonance frequency in the processing system 1 according to one example embodiment of the present disclosure will be described. In order to better understand a method of adjusting the resonance frequency in the processing system 1, first, a circuit 500 including a Josephson junction 501 and a capacitor 502 will be described. FIG. 1 is a diagram illustrating an example of a circuit 500 according to some example embodiments of the present disclosure. The circuit 500 includes the Josephson junction 501 and the capacitor 502. When a quantum bit device is configured by the circuit 500 as illustrated in FIG. 1, the resonance frequency defines the operation frequency. The resonance frequency of the circuit illustrated in FIG. 1 is 1/(2π(Lj·C)\hat{ }(½)) from an inductance Lj of the Josephson junction 501 and a capacitance C of the capacitor 502. Here, “\hat{ }” is a power operator. The inductance Lj is expressed by Equation (1) from a critical current value Ic of the Josephson junction 501 and a current I flowing through the Josephson junction 501.

$$\begin{matrix}[ Mathematical formula 1 ] & \\ L j = \frac{Φ 0}{2 π Ic} \frac{1}{\sqrt{1 - {( I / Ic )}^{2}}} & ( 1 )\end{matrix}$$

Here, Φ0 represents the magnitude of the magnetic flux quantum. As described above, the Josephson junction 501 has a non-linear inductance Lj. However, when the current I flowing through the Josephson junction 501 is sufficiently small, it can be treated as an inductor in which the magnitude of the inductance Lj is Φ0/(2πIc).

Next, a circuit 600 including an inductor 601 having a linear inductance Lk and a SQUID having a loop of two Josephson junctions 602a and 602b will be described. The inductance Lk of the SQUID changes by changing the magnetic flux inside the loop. The resonance frequency changes by the change in the inductance Lk. The magnetic flux can be generated by current flowing to a bias line inductively coupled to the SQUID loop. That is, the inductance Lk of the SQUID can be changed by current flowing to the bias line, and the resonance frequency can be ultimately changed. FIG. 2 is a diagram illustrating an example of a circuit 600 according to some example embodiments of the present disclosure. The circuit 600 includes the inductor 601 having a linear inductance Lk and the SQUID having a loop of two Josephson junctions 602a, 602b. Furthermore, as illustrated in FIG. 2, the circuit 600 includes a capacitor 603 having a capacitance C. Assuming that the critical current values of the respective Josephson junctions 602a and 602b are Ic1 and Ic2, the critical current value Ic_eff in the entire SQUID is expressed by Equation (2) by using the magnetic flux Φext threading through the inside of the SQUID.

$$\begin{matrix}[ Mathematical formula 2 ] & \\ Ic\_eff ( Φ ext ) = ( Ic 1 + Ic 2 ) \vert cos ( \frac{π Φ e x t}{Φ 0} ) \vert \sqrt{1 + {d}^{2} {tan}^{2} ( \frac{π {Φ}_{e x t}}{{Φ}_{0}} )} & ( 2 )\end{matrix}$$

Here, d=|Ic1−Ic2|/(Ic1+Ic2). In this case, the inductance Ls(Φext) of the SQUID is Ls(Φext)=Φ0/(2πIc_eff(Φext) in a range where the current flowing through the Josephson junctions 602a and 602b is sufficiently small. The resonance frequency f(Φext) is expressed by Equation (3).

$$\begin{matrix}[ Mathematical formula 3 ] & \\ f ( Φ e x t ) = \frac{1}{2 π \sqrt{( Ls ( Φ e x t ) + L k ) C}} & ( 3 )\end{matrix}$$

As shown in Equation (3), the resonance frequency f(Φext) has dependency on the magnetic flux Φext. That is, the resonance frequency f(Φext) can be adjusted by adjusting the magnetic flux Φext. When a plurality of quantum bit devices exist, the resonance frequency f(Φext) affects interaction among the plurality of quantum bit devices and the like. Therefore, it is desirable that the resonance frequency f(Φext) can be adjusted.

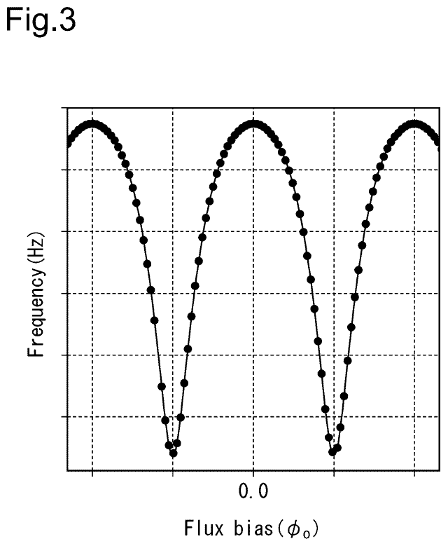

FIG. 3 is a diagram illustrating an example of magnetic field dependency of a resonance frequency of a quantum bit device in some example embodiments of the present disclosure. The magnetic field dependency of the resonance frequency of the quantum bit device illustrated in FIG. 3 is based on the assumption of the frequency of the SQUID in a case where two Josephson junctions of the SQUID are different and asymmetric. This asymmetric SQUID has a characteristic that the minimum value of the resonance frequency does not become zero. Therefore, when the measurement frequency is limited by an experimental equipment (e.g., when limited to 5 to 10 GHZ), the movable frequency region of the asymmetric SQUID is also adjusted in accordance with the frequency, thereby obtaining an advantage that the frequency can be always measured without losing sight. As can also be seen from Equation (2), the dependency of the resonance frequency on the magnetic flux has periodicity with respect to Φext. Then, the period becomes Φ0. The magnetic flux Φext threading through the inside of a certain SQUID is expressed by Equation (4) by using a current i flowing through a port inductively coupled to the SQUID with a magnitude M and a value of a residual magnetic flux Φoff existing inside the SQUID loop when no current is flowing.

$$\begin{matrix}[ Mathematical formula 4 ] & \\ Φ e x t = M \cdot i + Φ off & ( 4 )\end{matrix}$$

The residual magnetic flux Φoff in Equation (4) may change due to the influence of hysteresis or the influence of environment (e.g., temperature change etc.) when the current value i is changed.

In the description up to now, one quantum bit device has been considered, but actually, there are a plurality of quantum bit devices in one quantum chip. In such a case, the magnetic flux Φext_a threading through the SQUID in the a-th quantum bit device is also changed by a current flowing through a port inductively coupled to the SQUID in another quantum bit device. This is called crosstalk. Here, it is assumed that a port inductively coupled to the SQUID of the b-th quantum bit device is coupled to the SQUID in the a-th quantum bit device with a magnitude M_ab, and a current ib is flowing. In this case, the value of the magnetic flux Φext_a is expressed as Equation (5).

$$\begin{matrix}[ Mathematical formula 5 ] & \\ Φext\_a = {\sum }_{b} M\_ab \cdot ib + Φoff\_a & ( 5 )\end{matrix}$$

Here, Φoff_a represents a residual magnetic flux threading through the SQUID in the a-th quantum bit device. By changing the value of the magnetic flux Φext_a based on Equation (5), the resonance frequency of the a-th quantum bit device can be changed. The parameter that can be set in this case is the current ib flowing through each port. When the current value of the current ib is changed, not only one quantum bit device but all the quantum bit devices are affected. Therefore, it is necessary to set the current values of all the quantum bit devices in consideration of those influences.

Here, in order to collectively express magnetic fluxes for a chip having N quantum bit devices, variables such as Equations (6) to (9) are defined. Each of Φextv, Mv, Φoffv, and iv is a matrix and indicates a vector.

$$\begin{matrix}[ Mathematical formula 6 ] & \\ Φ etxv = ( \begin{matrix}Φ etx\_ 1 \\ ⋮ \\ Φ ext\_N\end{matrix} ) & ( 6 )\end{matrix}$$

$$\begin{matrix}[ Mathematical formula 7 ] & \\ Mv = ( \begin{matrix}M\_ 11 & … & M\_ 1 N \\ ⋮ & ⋱ & ⋮ \\ M\_N1 & … & M\_NN\end{matrix} ) & ( 7 )\end{matrix}$$

$$\begin{matrix}[ Mathematical formula 8 ] & \\ Φ offv = ( \begin{matrix}Φoff\_ 1 \\ ⋮ \\ Φoff\_N\end{matrix} ) & ( 8 )\end{matrix}$$

$$\begin{matrix}[ Mathematical formula 9 ] & \\ iv = ( \begin{matrix}i 1 \\ ⋮ \\ iN\end{matrix} ) & ( 9 )\end{matrix}$$

When Equations (6) to (9) are used, the magnetic flux Φextv in a case where a plurality of quantum bit devices are present is expressed by Equation (10).

$$\begin{matrix}[ Mathematical formula 10 ] & \\ Φ extv = Mv \cdot iv + Φ offv & ( 10 )\end{matrix}$$

Therefore, from Equation (10), in order to set the resonance frequency to a desired value, in a case where the magnetic flux Φtargetv to be set of the magnetic flux Φext is known, the value of the current iv to be set when there are a plurality of quantum bit devices can be calculated by Equation (11). The first term on the right side in Equation (11) represents an inverse matrix of the matrix Mv.

$$\begin{matrix}[ Mathematical formula 11 ] & \\ iv = {Mv}^{- 1} \cdot ( Φ targetv - Φ offv ) & ( 11 )\end{matrix}$$

### (Configuration of Processing System of Present Disclosure)

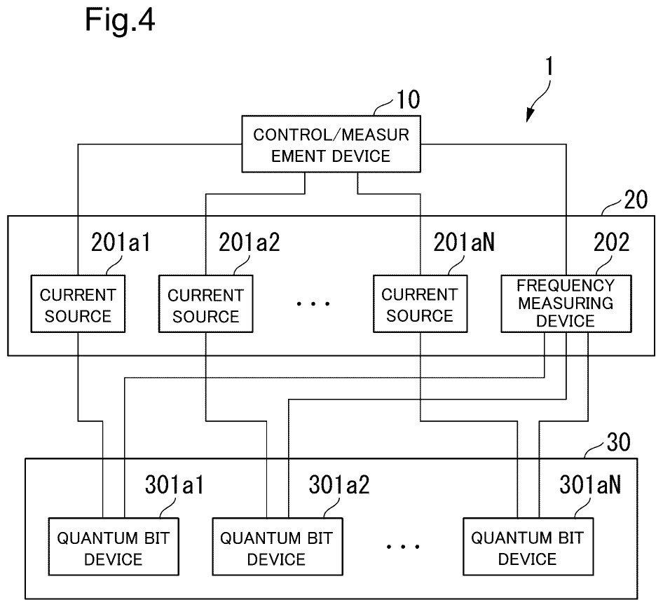

FIG. 4 is a diagram illustrating an example of a configuration of a processing system 1 according to some example embodiments of the present disclosure. As illustrated in FIG. 4, the processing system 1 according to one example embodiment of the present disclosure includes a control/calculation device 10, a control/measurement device 20, and a quantum chip 30.

The control/calculation device 10 controls the control/measurement device 20. For example, the control/calculation device 10 outputs measurement conditions to be measured by the control/measurement device 20 to the control/measurement device 20. Furthermore, for example, the control/calculation device 10 outputs the value of the current to be output from the control/measurement device 20 to the quantum chip 30 to the control/measurement device 20. In addition, the control/calculation device 10 performs a predetermined calculation by using a result of measurement by the control/measurement device 20. Details of the processing performed by the control/calculation device 10 will be described later.

As illustrated in FIG. 4, the control/measurement device 20 includes current sources 201a1, 201a2, . . . , and 201aN, and a frequency measuring device 202. Hereinafter, the current sources 201a1, 201a2, . . . , and 201aN may be collectively referred to as a current source 201. The control/measurement device 20 controls the quantum chip 30. For example, each of the current sources 201 of the control/measurement device 20 controls the oscillation frequency of each quantum bit device 301 by causing a current to flow to a corresponding quantum bit device 301 described later included in the quantum chip 30. Specifically, the current source 201a1 controls the oscillation frequency of the quantum bit device 301a1 by causing a current to flow to the quantum bit device 301a1. Furthermore, the current source 201a2 controls the oscillation frequency of the quantum bit device 301a2 by causing a current to flow to the quantum bit device 301a2. In addition, the current source 201aN controls the oscillation frequency of the quantum bit device 301aN by causing a current to flow to the quantum bit device 301aN.

In addition, the control/measurement device 20 performs a measurement on the quantum chip 30. For example, the frequency measuring device 202 of the control/measurement device 20 performs a measurement necessary for adjusting the oscillation frequency of each quantum bit device 301 in the quantum chip 30. For example, the frequency measuring device 202 is a network analyzer. Details of the processing performed by the control/measurement device 20 will be described later.

As illustrated in FIG. 4, the quantum chip 30 includes quantum bit devices 301a1, 301a2, . . . , and 301aN. The quantum bit devices 301a1, 301a2, . . . , and 301aN may be collectively referred to as a quantum bit device 301. Each of the quantum bit devices 301 resonates according to the current supplied from the current source 201. The quantum bit device 301 indicates a quantum bit device. For example, the quantum bit device 301 includes a circuit 600 having the SQUID illustrated in FIG. 2.

The above-described processing performed by the processing system 1 according to one example embodiment of the present disclosure is an example, and is not limited to the above-described process. For example, the processing system 1 may perform the processing described below.

### (Processing Performed by Processing System of Present Disclosure)

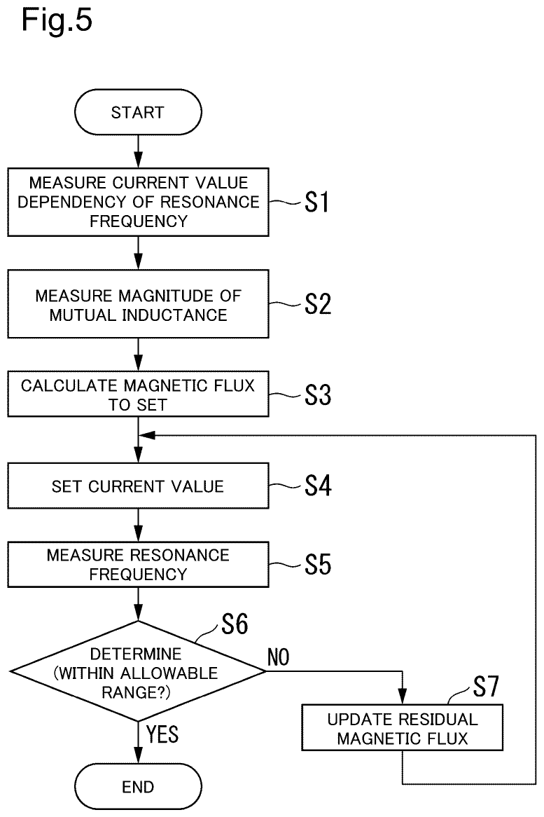

FIG. 5 is a diagram illustrating an example of a processing flow of the processing system 1 according to some example embodiments of the present disclosure. Here, the processing of steps S1 to S7 for adjusting the oscillation frequency of the quantum bit device 301 performed by the processing system 1 illustrated in FIG. 5 will be described.

### (Processing of Step S1)

Step S1 is a processing of measuring the current value dependency of the resonance frequency f(Φext).

In step S1, the value of the diagonal component in the inductance matrix Mv is obtained.

The processing system 1 measures the current value dependency of the resonance frequency f(Φext) of each quantum bit device. Specifically, the control/calculation device 10 outputs the measurement conditions to be measured by the frequency measuring device 202 of the control/measurement device 20 to the frequency measuring device 202. Examples of the measurement conditions include the strength of a signal output to each of the quantum bit devices 301, measurement items such as reflection measurement and equivalent measurement, and the like. In addition, the control/calculation device 10 outputs, to the current source 201, the current value of the current output from each of the current sources 201 of the control/measurement device 20 to the corresponding quantum bit device 301. The current source 201 changes the current value for each measurement of the 1 to N quantum bit devices of the quantum bit device 301a1 to 301aN.

Here, the current value of the current caused to flow to the a-th quantum bit device of the quantum bit devices 301a1 to 301aN is defined as ia. In this case, while the current source 201 changes the current value ia, the frequency measuring device 202 measures the resonance frequency f(Φext) for the a-th quantum bit device according to the measurement condition. At this time, the current values of the quantum bit devices other than the a-th quantum bit device to be measured are set to a constant value, for example, all 0. A person sets the current value ia and the measurement condition in the control/calculation device 10 in advance.

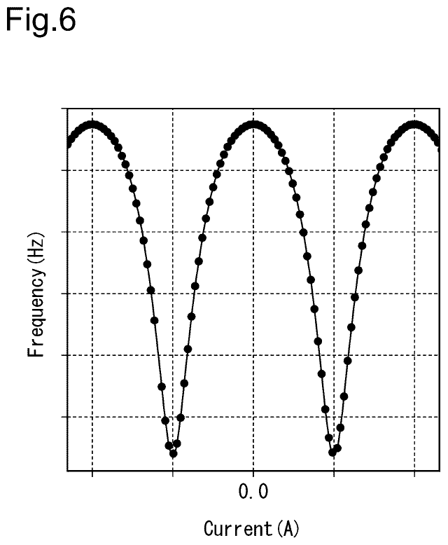

FIG. 6 is a diagram illustrating an example of a measurement result by a frequency measuring device 202 according to some example embodiments of the present disclosure. An example of the measurement result illustrated in FIG. 6 is a measurement result for an asymmetric SQUID in which critical current values of two Josephson junctions of the SQUID are different, similarly to the magnetic field dependency of the resonance frequency of the quantum bit device illustrated in FIG. 3. In FIG. 6, the horizontal axis represents the current value. Furthermore, the vertical axis represents the resonance frequency f(Φext). The frequency measuring device 202 obtains one resonance frequency as a measurement result for one current value ia. That is, the frequency measuring device 202 obtains one of the points as illustrated in FIG. 6 by performing reflection measurement, transmission measurement, and the like on the a-th one of the quantum bit devices 301a1 to 301aN. Then, the frequency measuring device 202 performs a similar measurement on all the quantum bit devices 301a1 to 301aN to obtain measurement results of N points capable of drawing a graph as illustrated in FIG. 6. The frequency measuring device 202 outputs the measurement results of the N points to the control/calculation device 10.

Each of the quantum bit devices 301 includes the circuit 600 illustrated in FIG. 2. In this case, it is known that the resonance frequency f(Φext) is determined from the linear inductance Lk, the capacitance C, and the critical current values Ic1 and Ic2 of the Josephson junction Jj of the circuit. Therefore, for example, the values of the critical current values Ic1 and Ic2 are obtained from fitting of the data point (i.e., measurement results of N points measured by the frequency measuring device 202) and Equation (3) that is the analytic formula. In addition, for example, a current value necessary for changing the magnetic flux by Φ0 is obtained by the periodicity of the resonance frequency f(Φext). Here, any method may be used as long as a function for reproducing the magnetic field dependency of the resonance frequency f(Φext) can be obtained. Therefore, the values of the critical current values Ic1 and Ic2 are not limited to being obtained by fitting the data point and the Equation (3). For example, the parameter used as the data point may be other than those described above, and an equation other than Equation (3) suitable for the parameter may be used. In addition, other methods may be used.

The control/calculation device 10 obtains the critical current values Ic1 and Ic2 of the Josephson junction Jj in the circuit 600 of each quantum bit device 301 by fitting the measurement results of the N points measured by the frequency measuring device 202 and the Equation (3). Then, the control/calculation device 10 obtains the dependency f(Φext_a)_a of the resonance frequency f(Φext) and the magnetic flux Φext and the dependency Φext (ia)_a of the magnetic flux Φext and the current value ia for all the quantum bit devices 301a1 to 301aN as shown in Equations (3) and (4) for each of the quantum bit devices 301.

Therefore, the frequency measuring device 202 performs reflection measurement, transmission measurement, and the like on all the quantum bit devices 301a1 to 301aN, thereby obtaining the dependency f(Φext_a)_a of the resonance frequency f(Φext) and the magnetic flux Φext and the dependency Φext (ia)_a of the magnetic flux Φext (i) and the current value i for the a-th quantum bit device of the quantum bit device 301. Then, an inductance component M_aa of the a-th bit in the inductance matrix Mv expressed by Equation (7) is obtained. In addition, the residual magnetic flux component Φoff_a of the a-th bit in the matrix Φoffv of the residual magnetic flux for the a-th quantum bit device 301 is also obtained by the magnetic flux at the current value ia=0.

### (Processing of Step S2)

Step S2 is a processing of measuring the magnitude of the mutual inductance. In step S2, the values of the non-diagonal components other than the diagonal components obtained in step S1 in the inductance matrix Mv are obtained.

When obtaining the mutual inductance M_ab of the port of the b-th quantum bit device 301 with respect to the a-th quantum bit device 301, the frequency measuring device 202 measures the resonance frequency f(Φext) of the a-th quantum bit device 301 according to the measurement condition while the current source 201 changes the current value ib of the current flowing through the b-th quantum bit device 301.

The measurement of the resonance frequency f(Φext) of the a-th quantum bit device 301 is reflection measurement, transmission measurement, or the like. A person sets the current value ia and the measurement condition in the control/calculation device 10 in advance. The b-th quantum bit device 301 is one of the quantum bit devices 301 other than the a-th quantum bit device 301. In this measurement, the current value flowing through the quantum bit device 301 other than the b-th quantum bit device 301 is set to a constant value. For example, the current value ia of the current flowing through the a-th quantum bit device 301 is set such that the magnetic flux in the SQUID loop becomes Φ0/4, and the current values of the currents flowing through the other quantum bit devices 301 are all set to 0. The amount of change in the resonance frequency f(Φext) when the magnetic flux Φext changes can be increased by making the magnetic flux Φext inside the SQUID loop of the a-th quantum bit device 301 to be measured finite. The frequency measuring device 202 performs a similar measurement on all the quantum bit devices 301a1 to 301aN. Then, the frequency measuring device 202 outputs the measurement result to the control/calculation device 10.

In a case where all the current values other than the current values ia and ib are 0, the magnetic flux Φext_a of the a-th quantum bit device 301 is expressed by Equation (12).

$$\begin{matrix}[ Mathematical formula 12 ] & \\ Φext\_a = M\_aa \cdot ia + M\_ab \cdot ib + Φoff\_a & ( 12 )\end{matrix}$$

The control/calculation device 10 obtains M_ab by using the relationship between the resonance frequency f(Φext)_a of the a-th quantum bit device 301 measured in step S1, the internal magnetic flux Φext_a, and Equation (12).

### (Processing of Step S3)

Step S3 is a processing of calculating the magnetic flux to be set. The control/calculation device 10 calculates the magnetic flux Φtarget_a to be set by solving ftarget_a=f(Φtarget_a)_a for the resonance frequency ftarget_a to be set in each of the quantum bit devices 301.

The resonance frequency f(Φext_a)_a is generally an even function. Therefore, f(Φext_a)=f(−Φext_a)_a. Furthermore, considering the periodicity of the resonance frequency f(Φext_a)_a, the magnetic flux to be set is Φtarget_a+nΦ0 or −Φtarget_a+nΦ0. Here, n is an integer. Generating a large magnetic flux causes an excessive current to flow, which is undesirable for the superconducting device. Therefore, it is desirable to set the range of the magnetic flux Φtarget_a to −Φ0/2<Φtarget_a<Φ0/2. In addition, the required value of the current value varies depending on the combination of the signs of the magnetic fluxes. For example, in a case of N quantum bit devices 301, 2\hat{ }N combinations exist. However, the number of calculations increases exponentially as the number N of quantum bit devices 301 increases. Therefore, when the number of quantum bit devices 301 is large, the sign of Φtarget_a to be set is determined according to the sign of the residual magnetic flux Φoff_a of each quantum bit device 301 in order to reduce the number of calculations and reduce the change in the current value of the current flowing from the current source 201 to the quantum bit device 301. For example, in the case of the quantum bit device 301 in which the magnetic flux Φ0 is affected to the plus side due to crosstalk, the resonance frequency existing in the range of the magnetic flux Φ0 on the plus side within the range of −Φ0/2<Φtarget_a<Φ0/2 is set as Φtarget_a.

The control/calculation device 10 desirably specifies the smallest current by performing calculation 2\hat{ }N times, and sets the current value of the specified current to the final current value. Therefore, the control/calculation device 10 may set all combinations of current values in the current source 201, specify the smallest current by calculating 2\hat{ }N times, and set the current value of the specified current as the final current value.

### (Processing of Step S4)

Step S4 is a processing of calculating a current value to be set. The control/calculation device 10 calculates a current value to be set according to Equation (11). At this time, the control/calculation device 10 calculates the current value according to the sign of Φtarget_a determined in accordance with the sign of the residual magnetic flux Φoff_a of each quantum bit device 301 in step S3. As another example, the control/calculation device 10 may calculate the current value for all the combinations of the signs of the magnetic fluxes described above, and may redefine the combination of the signs with which the sum of squares of the calculated current values is minimum as the sign of each element of Φtarget.

### (Processing of Step S5)

Step S5 is a processing of measuring the resonance frequency f(Φext). The control/calculation device 10 sets the current value calculated in step S4 for each of the current sources 201.

Each of the current sources 201 causes a current of a set current value to flow to the corresponding quantum bit device 301. Then, similarly to the measurement of the resonance frequency f (Øext) in step S1, the frequency measuring device 202 measures the resonance frequency f(Φext) by reflection measurement or transmission measurement of the a-th quantum bit device 301 according to the measurement condition. Then, the frequency measuring device 202 outputs the measurement result to the control/calculation device 10.

### (Processing of Step S6)

Step S6 is a processing of making a determination. The control/calculation device 10 calculates Δf_a=fmeasure_a−ftarget_a with the resonance frequency f(Φext) measured by the frequency measuring device 202 in step S5 as fmeasure_a. The control/calculation device 10 determines whether the calculated Δf_a is within a predetermined allowable error range. When determining that Δf_a is within the predetermined allowable error range, the control/calculation device 10 terminates the processing. When determining that Δf_a is outside the predetermined allowable error range, the control/calculation device 10 proceeds to the processing of step S7.

### (Processing of Step S7)

Step S7 is a processing of updating the residual magnetic flux. The control/calculation device 10 updates the value of the residual magnetic flux Φoff based on fmeasure_a, which is the resonance frequency f(Φext) measured by the frequency measuring device 202 in step S5. For example, fmeasure_a=f(Φmeasure_a)_a is solved by using the relationship of f(Φext_a)_a obtained by the control/calculation device in step S1. As a result, the control/calculation device 10 can obtain the magnetic flux measure_a at the current time point. In addition, a new residual magnetic flux [Φ] _offv can be expressed as Equation (13) by using the current value iv and the inductance matrix Mv input at the current time point.

$$\begin{matrix}[ Mathematical formula 13 ] & \\ [ Φ ] \_offv = Φ measurev - Mv \cdot iv & ( 13 )\end{matrix}$$

The control/calculation device 10 substitutes the new residual magnetic flux [Φ] _offv shown in Equation (13) into Φoffv of Equation (11), and calculates a current value similar to step S4.

Through the above processing process, a minute change in the residual magnetic flux due to the flow of current to the port of each quantum bit device 301 can be corrected, and the frequencies of all the quantum bit devices can be simultaneously set.

### (Advantages)

The processing system 1 according to one example embodiment of the present disclosure has been described above. The processing system 1 includes a control/calculation device 10 (an example of a calculation means) for calculating a first current value that is a current value of a current flowing through the circuit 600 based on a value of a residual magnetic flux Φoff in the circuit 600 (an example of a resonator circuit) included in the quantum bit device 301. According to this processing system 1, the resonance frequency can be adjusted with high accuracy.

### Modified Example of Example Embodiment

A processing system 1 according to a modified example of one example embodiment of the present disclosure will be described. A processing system 1 according to the modified example of one example embodiment of the present disclosure is a system that reuses a measurement result of a resonance frequency performed in the past. The measurement result of the resonance frequency performed in the past is, for example, a measurement result of the processing of step S1 and the processing of step S2 in one example embodiment of the present disclosure performed in the past by the processing system 1, and is a measurement result that can indicate the relationship as illustrated in FIGS. 3 and 6. The dependency f(Φext_a)_a of the inductance matrix Mv, the resonance frequency, and the magnetic flux is determined by the structure of the quantum bit device 301. Therefore, measurement results performed in the past can be reused.

### (Configuration of Processing System)

The processing system 1 according to the modified example of one example embodiment of the present disclosure has a configuration similar to that of the processing system 1 illustrated in FIG. 4. For example, when the quantum chip 30 including the quantum bit device 301 is once brought into a not very low temperature state and brought into a very low temperature state again, only the residual magnetic flux Φoff changes. Therefore, the processing system 1 can complete the adjustment of the frequency in a short time by reusing the measurement result of the resonance frequency performed in the past and updating only the residual magnetic flux Φoff. Specifically, for example, when the quantum chip 30 is transferred to a refrigerator installed for performing quantum computing after the characteristics are evaluated in the refrigerator installed for basic characteristics evaluation, it is useful for the processing system 1 to reuse the measurement results of the resonance frequency performed in the past. Furthermore, when the refrigerator is continuously operated for a long time, an operation of removing impurities in the circulating gas may be required. Even when the inside of the refrigerator is no longer in the very low temperature state, it is useful to reuse the measurement results of the resonance frequency performed in the past.

### (Processing Performed by Processing System)

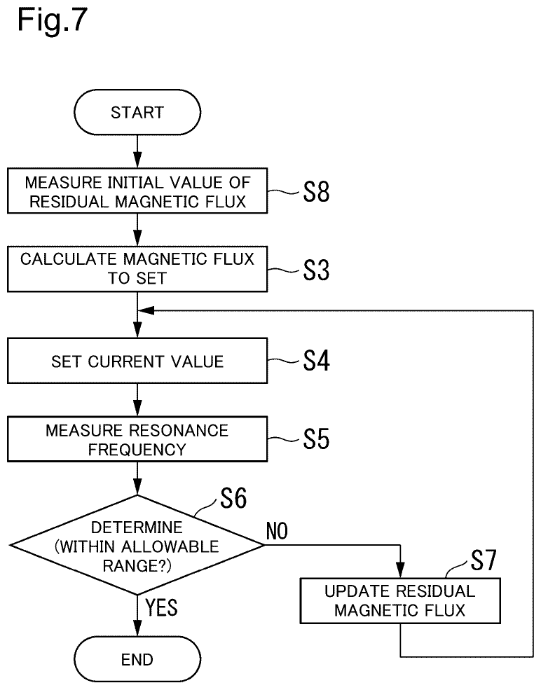

FIG. 7 is a diagram illustrating an example of a processing flow of the processing system 1 according to some example embodiments of the present disclosure. Here, processing of step S8 performed by the processing system 1 illustrated in FIG. 7 instead of the processing of step S1 and the processing of step S2 of the processing flow illustrated in FIG. 5 will be described.

### (Processing of Step S8)

Step S8 is a processing of performing an initial value measurement of the residual magnetic flux. Specifically, in the processing system 1, the control/calculation device 10 outputs the measurement conditions to be measured by the frequency measuring device 202 of the control/measurement device 20 to the frequency measuring device 202. Examples of the measurement conditions include the strength of a signal output to each of the quantum bit devices 301, measurement items such as reflection measurement and equivalent measurement, and the like. In addition, the control/calculation device 10 outputs, to the current source 201, the current value of the current output from each of the current sources 201 of the control/measurement device 20 to the corresponding quantum bit device 301. The current source 201 changes the current value for each measurement of the 1 to N quantum bit devices of the quantum bit device 301a1 to 301aN.

In this case, while the current source 201 changes the current value ia, the frequency measuring device 202 measures the resonance frequency f(Φext) for the a-th quantum bit device according to the measurement condition. At this time, the current values of the quantum bit devices other than the a-th quantum bit device to be measured are set to a constant value, for example, all 0. In step S8, unlike step S1, the inductance matrix Mv, the resonance frequency, and the magnetic flux dependency f(Φext_a)_a determined by the structure of the quantum bit device 301 are already known. Therefore, while the current source 201 changes the current value ia, the frequency measuring device 202 may perform a measurement of the resonance frequency f(Φext) for two or more a-th quantum bit devices according to the measurement condition.

In a case where the frequency measuring device 202 measures the resonance frequency f(Φext) only for one a-th quantum bit device according to the measurement condition while the current source 201 changes the current value ia, it is possible to measure the absolute value of the residual magnetic flux Φoff. However, in this case, it is impossible to specify the sign of the residual magnetic flux Φoff. For example, a current value for changing the magnetic flux in the SQUID of the a-th quantum bit device 301 by Φ0/10 is i(a, 1/10). In this case, the sign of the residual magnetic flux Φoff is determined from the resonance frequency f(Φext) when ia=0 and the resonance frequency f(Φext) when ia=i(a, 1/10). However, when the residual magnetic flux Φoff is substantially 0, it is difficult to distinguish whether the sign of the residual magnetic flux Φoff is plus or minus. However, in such a case, regardless of the sign of the residual magnetic flux Φoff, the residual magnetic flux can be set to a correct value in the processing of updating the residual magnetic flux in step S7, and thus, there is no problem in practice. After performing the processing of step S8, the processing system 1 performs processing similar to the processing of steps S3 to S7 described in the one example embodiment of the present disclosure.

### (Advantages)

The processing system 1 according to the modified example of one example embodiment of the present disclosure has been described above. In the processing system 1, the measurement result of the resonance frequency performed in the past is reused, and while the current source 201 changes the current value ia, the frequency measuring device 202 measures the resonance frequency f(Φext) for two or more a-th quantum bit devices according to the measurement condition. With the processing system 1, the processing can be reduced, and the adjustment of the resonance frequency can be completed in a short time.

### Another Modified Example of Example Embodiment

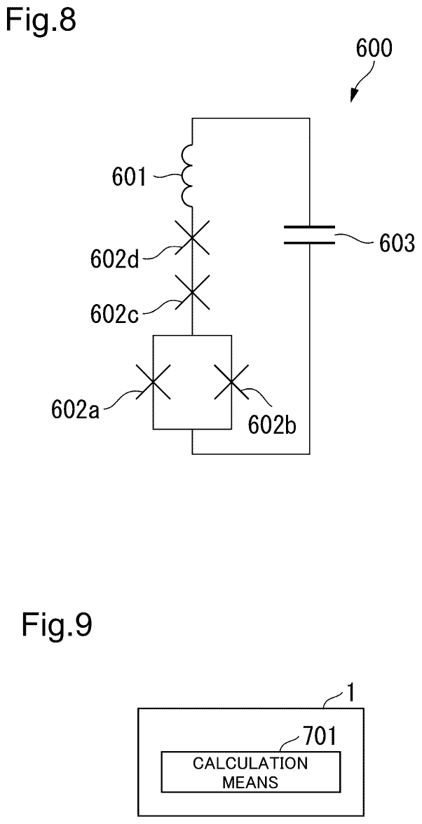

In one example embodiment of the present disclosure and the modified example of one example embodiment of the present disclosure, the circuit 600 has been described as including the inductor 601, the Josephson junctions 602a and 602b, and the capacitor 603 as illustrated in FIG. 2. However, the circuit 600 is not limited to the circuit illustrated in FIG. 2. For example, the circuit 600 may include a SQUID having one or more Josephson junctions in series with parallel connected Josephson junctions, and FIG. 8 is a diagram illustrating an example of a circuit 600 according to some example embodiments of the present disclosure. In another modified example of one example embodiment of the disclosure, for example, the circuit 600 may include an inductor 601, Josephson junctions 602a, 602b, 602c, 602d, and a capacitor 603, as illustrated in FIG. 8. The circuit 600 illustrated in FIG. 8 includes a SQUID in which two Josephson junctions 602c and 602d are connected in series to the Josephson junctions 602a and 602b connected in parallel in the SQUID illustrated in FIG. 2. In the case of the circuit 600 illustrated in FIG. 8, Equation (3) needs to be changed by an amount corresponding to two Josephson junctions 602c and 602d connected in series.

In the processing system 1 according to each example embodiment of the present disclosure described above, description has been made that there are a plurality of quantum bit devices, and the processing uses a matrix. However, in the processing system 1 according to another example embodiment of the present disclosure, the processing can be performed even in a case where there is one quantum bit device. In that case, the processing system 1 according to another example embodiment of the present disclosure may regard each of Φextv, Mv, Φoffv, and iv in the equations of the above description as one row and one column and perform a similar procedure as the processing system 1 according to each example embodiment of the present disclosure. However, the first term on the right side of Equation (11) is not an inverse matrix of Mv but an inverse thereof, and the processing system 1 according to another example embodiment of the present disclosure skips the processing of step S2 of obtaining the non-diagonal component of the matrix. Even in a case where there is one quantum bit device, residual magnetic flux can be generated. Therefore, it is meaningful that the processing system 1 according to another example embodiment of the present disclosure executes the processing of setting the residual magnetic flux described in each example embodiment of the present disclosure described above to a correct value even in a case where there is one quantum bit device.

FIG. 9 is a diagram illustrating an example of a configuration of the processing system 1 according to some example embodiments of the present disclosure. As illustrated in FIG. 9, the processing system 1 includes a calculation means 701.

The calculation means 701 calculates a first current value, which is a current value of a current flowing through the resonator circuit, based on a value of a residual magnetic flux in the resonator circuit of the quantum bit device.

The calculation means 701 can be achieved by using, for example, the functions of the control/calculation device 10 illustrated in FIG. 4.

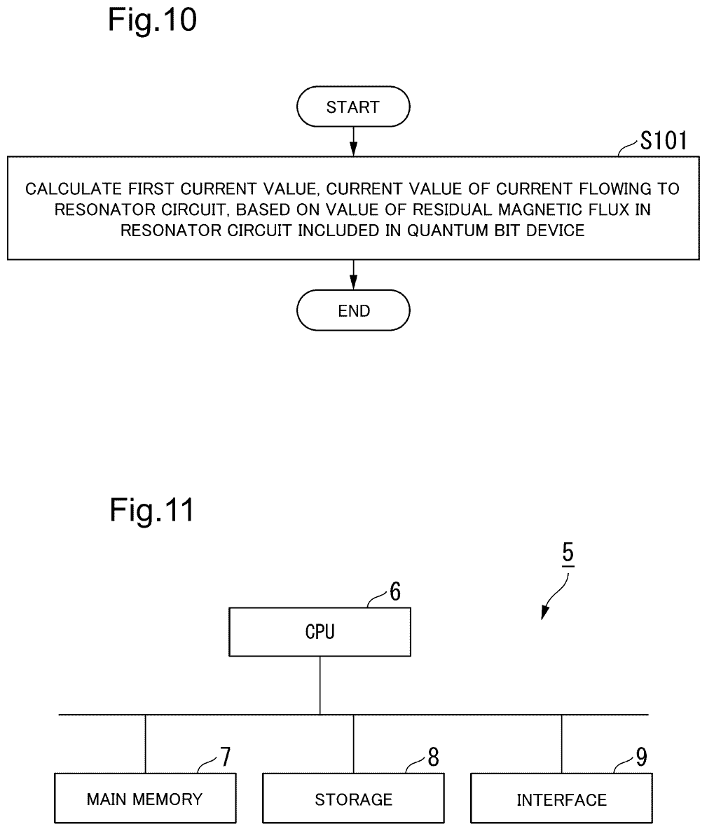

Next, processing performed by the processing system 1 according to some example embodiments of the present disclosure will be described. FIG. 10 is a diagram illustrating an example of a processing flow of the processing system 1 according to some example embodiments of the present disclosure. Here, the processing of the processing system 1 will be described with reference to FIG. 10.

The calculation means 701 calculates a first current value, which is a current value of a current flowing through the resonator circuit, based on a value of a residual magnetic flux in the resonator circuit of the quantum bit device (step S101).

The processing system 1 according to some example embodiments of the present disclosure has been described above. According to this processing system 1, the resonance frequency can be adjusted with high accuracy.

The order of processing in each example embodiment of the present disclosure may be changed within a range in which appropriate processing is performed.

Although each example embodiment of the present disclosure has been described, the processing system 1, the control/calculation device 10, the control/measurement device 20, and other control devices described above may include a computer system therein. The processing of the above-described processing is stored in a computer-readable recording medium in the form of a program, and the above-described processing is performed by the computer reading and executing the program. A specific example of the computer will be described below.

FIG. 11 is a schematic block diagram illustrating a configuration of a computer according to at least one example embodiment. As illustrated in FIG. 11, the computer 5 includes a central processing unit (CPU) 6, a main memory 7, a storage 8, and an interface 9.

For example, each of the processing system 1, the control/calculation device 10, the control/measurement device 20, and other control devices described above is mounted on the computer 5. Then, the operation of each processing unit described above is stored in the storage 8 in the form of a program. The CPU 6 reads the program from the storage 8, develops the program in the main memory 7, and executes the above processing according to the program. In addition, the CPU 6 secures a storage area corresponding to each of the above-described storage units in the main memory 7 according to the program.

Examples of the storage 8 include a hard disk drive (HDD), a solid state drive (SSD), a magnetic disk, a magneto-optical disk, a compact disc read only memory (CD-ROM), a digital versatile disc read only memory (DVD-ROM), a semiconductor memory, and the like. The storage 8 may be an internal medium directly connected to the bus of the computer 5 or an external medium connected to the computer 5 via the interface 9 or a communication line. In addition, in a case where the program is distributed to the computer 5 through a communication line, the computer 5 that has received the distribution may develop the program in the main memory 7 and execute the above processing. In at least one example embodiment, the storage 8 is a non-transitory tangible storage medium.

In addition, the program may achieve a part of the functions described above. Furthermore, the program may be a file that can achieve the above-described functions in combination with a program already recorded in the computer system, that is, a so-called difference file (difference program).

Although some example embodiments of the present disclosure have been described, these example embodiments are examples and do not limit the scope of the disclosure. Various additions, omissions, substitutions, and changes may be made to these example embodiments within a scope not deviating from the gist of the disclosure.

Some or all of the above example embodiments may be described as the following Supplementary Notes, but are not limited to the following.

### (Supplementary Note 1)

A processing system including:
a calculation means for calculating a first current value based on a value of a residual magnetic flux in a resonator circuit included in a quantum bit device, the first current value being a current value of a current flowing through the resonator circuit.

### (Supplementary Note 2)

The processing system according to supplementary note 1, in which
the calculation means,
calculates the first current value based on a matrix having an element obtained based on a measurement result of a resonance frequency of the resonator circuit.

### (Supplementary Note 3)

The processing system according to supplementary note 1 or 2, further including:
a first setting means for setting the first current value as a current value of a current source for a current flowing to the resonator circuit.

### (Supplementary Note 4)

The processing system according to any one of supplementary notes 1 to 3, in which
the calculation means,
calculates the first current value by using a value after correction of a residual magnetic flux as a value of the residual magnetic flux in the resonator circuit.

### (Supplementary Note 5)

The processing system according to supplementary note 4, further including:
a second setting means for setting the first current value calculated by the calculation means as a current value of a current source for a current flowing to the resonator circuit.

### (Supplementary Note 6)

The processing system according to any one of supplementary notes 2 to 5, further including:
a first measurement means for measuring the resonance frequency of the resonator circuit.

### (Supplementary Note 7)

The processing system according to any one of supplementary notes 1 to 6, further including:
a second measurement means for measuring an initial value of the residual magnetic flux.

### (Supplementary Note 8)

A processing method including calculating a first current value based on a matrix having an element obtained based on a measurement result of a resonance frequency of the resonator circuit included in a quantum bit device and a value of a residual magnetic flux in the resonator circuit, the first current value being a current value of a current flowing through the resonator circuit.

### (Supplementary Note 9)

The processing method according to supplementary note 8, further including calculating the first current value based on a matrix having an element obtained based on a measurement result of a resonance frequency of the resonator circuit.

### (Supplementary Note 10)

The processing method according to supplementary note 8 or 9, further including setting the first current value as a current value of a current source for a current flowing to the resonator circuit.

### (Supplementary Note 11)

The processing method according to any one of supplementary notes 8 to 10, further including calculating the first current value by using a value after correction of a residual magnetic flux as a value of the residual magnetic flux in the resonator circuit.

### (Supplementary Note 12)

The processing method according to supplementary note 11, further including setting the calculated first current value as a current value of a current source for a current flowing to the resonator circuit.

### (Supplementary Note 13)

The processing method according to any one of supplementary notes 9 to 12, further including:

measuring the resonance frequency of the resonator circuit.

### (Supplementary Note 14)

The processing method according to any one of supplementary notes 8 to 13, further including:

measuring an initial value of the residual magnetic flux.

### (Supplementary Note 15)

A program for causing a computer to execute calculating a first current value based on a matrix having an element obtained based on a measurement result of a resonance frequency of the resonator circuit included in a quantum bit device and a value of a residual magnetic flux in the resonator circuit, the first current value being a current value of a current flowing through the resonator circuit.

### (Supplementary Note 16)

The program according to supplementary note 15, further causing the computer to execute calculating the first current value based on a matrix having an element obtained based on a measurement result of a resonance frequency of the resonator circuit.

### (Supplementary Note 17)

The program according to supplementary note 15 or 16, further causing the computer to execute setting the first current value as a current value of a current source for a current flowing to the resonator circuit.

### (Supplementary Note 18)

The program according to any one of supplementary notes 15 to 17, further causing the computer to execute calculating the first current value by using a value after correction of a residual magnetic flux as a value of the residual magnetic flux in the resonator circuit.

### (Supplementary Note 19)

The program according to supplementary note 18, further causing the computer to execute setting the calculated first current value as a current value of a current source for a current flowing to the resonator circuit.

### (Supplementary Note 20)

The program according to any one of supplementary notes 16 to 19, further causing the computer to execute measuring the resonance frequency of the resonant circuit.

### (Supplementary Note 21)

The program according to any one of supplementary notes 15 to 20, further causing the computer to execute measuring an initial value of the residual magnetic flux.

1. A processing system comprising:
at least one memory storing instructions; and
at least one processor configured to execute the instructions to:
calculate a first current value based on a value of a residual magnetic flux in a resonator circuit included in a quantum bit device, the first current value being a current value of a current flowing through the resonator circuit.

2. The processing system according to claim 1, wherein the at least one processor is further configured to execute the instructions to:
calculate the first current value based on a matrix having an element obtained based on a measurement result of a resonance frequency of the resonator circuit.

3. The processing system according to claim 1, wherein the at least one processor is further configured to execute the instructions to:
set the first current value as a current value of a current source for a current flowing to the resonator circuit.

4. The processing system according to claim 1, wherein the at least one processor is further configured to execute the instructions to:
calculate the first current value by using a value after correction of a residual magnetic flux as a value of the residual magnetic flux in the resonator circuit.

5. The processing system according to claim 4, wherein the at least one processor is further configured to execute the instructions to:
set the first current value calculated as a current value of a current source for a current flowing to the resonator circuit.

6. The processing system according to claim 2, wherein the at least one processor is further configured to execute the instructions to:
measure the resonance frequency of the resonator circuit.

7. The processing system according to claim 1, wherein the at least one processor is further configured to execute the instructions to:
measure an initial value of the residual magnetic flux.

8. A processing method comprising:
calculating a first current value based on a value of a residual magnetic flux in a resonator circuit included in a quantum bit device, the first current value being a current value of a current flowing through the resonator circuit.

9. A non-transitory computer-readable recording medium having recorded therein a program causing a computer to execute:
calculating a first current value based on a value of a residual magnetic flux in a resonator circuit included in a quantum bit device, the first current value being a current value of a current flowing through the resonator circuit.
